(19) United States
(12) Patent Application Publication
(10) Pub. No.: US 2026/0247904 A1
(43) Pub. Date: Aug. 20, 2026

(54) HEAT DISSIPATION MATERIAL ATTACHING APPARATUS, HEAT DISSIPATION MATERIAL FEEDING METHOD, AND HEAT DISSIPATION MATERIAL ATTACHING METHOD

(71) Applicant: HORNG TERNG AUTOMATION CO., LTD., Kaohsiung City (TW)

(72) Inventors: Yu-Hsien WANG, Kaohsiung City (TW); Chih-Yuan LIN, Kaohsiung City (TW); Yuan-Yi CHANG, Kaohsiung City (TW); Jian-Hua CHEN, Kaohsiung City (TW)

(21) Appl. No.: 19/333,386

(22) Filed: Sep. 19, 2025

(30) Foreign Application Priority Data
Feb. 17, 2025 (TW) 114105756

(51) Int. Cl. H10P 72/00

(52) U.S. Cl. CPC H10P 72/0438

(57) ABSTRACT

A heat dissipation material attaching apparatus includes a platform, a first feeding module, a second feeding module, a first deployment module, and a second deployment module. The platform includes a first feeding region and a second feeding region. The first and the second feeding region have respectively a first concave and a second concave recessed into the platform. The first and the second feeding module are disposed detachably in the first or the second concave, and configured to feed the first and the second heat dissipation materials respectively. The first feeding and the second module are different, and sizes of the first and the second heat dissipation materials are different. The first deployment module and the second deployment module are disposed movably on the platform and configured to suck, deliver and attach the first or the second heat dissipation materials from the first and the second feeding region.

### CROSS - REFERENCE TO RELATED APPLICATION

This application claims priority to Taiwan Application Serial Number 114105756, filed February 17, 2025, which is herein incorporated by reference in its entirety.

### BACKGROUND

### Field of Invention

The present disclosure relates to a semiconductor packaging technology, and more particularly, to a heat dissipation material attaching apparatus, a heat dissipation material feeding method, and a heat dissipation materials attaching method.

### Description of Related Art

In the semiconductor packaging field, heat dissipation material attaching apparatuses are usually equipped with one single feeding device. Therefore, the heat dissipation material attaching apparatus can only perform a heat dissipation material attaching process with one single product size during operation.

However, in the heat dissipation material attaching process, there is a need to attach materials of different sizes, and conventional heat dissipation material apparatuses cannot continuously perform heat dissipation material attaching operations for materials of different sizes. When the product needs to be continuously attached with heat dissipation materials of different sizes, two or more apparatuses with different feeding modules are required to complete the attaching of the heat dissipation materials of the different sizes.

In addition, in this feeding mode, it is necessary to wait until the entire batch of products complete the attachment of the heat dissipation materials of the first size on the first apparatus before performing the attachment of the heat dissipation materials of the second size on the second apparatus. The method illustrated above is complicated, consumes additional waiting time, and requires more apparatuses and more space.

### SUMMARY

Therefore, one objective of the present disclosure is to provide a heat dissipation material attaching apparatus, a heat dissipation material feeding method, and a heat dissipation material attaching method, which can meet the attaching requirement of various heat dissipation materials in the heat dissipation material attaching process. Accordingly, the operation process can be simplified, and the waiting time of the operation can be saved.

According to the objective of the present disclosure, a heat dissipation attaching apparatus is provided, which includes a platform, at least one first feeding module, at least one second feeding module, a first deployment module, and a second deployment module. The platform includes a first feeding region and a second feeding region. The first feeding region and the second feeding region respectively have a first concave and a second concave recessed into the platform. The at least one first feeding module is detachably disposed in the first concave or the second concave, and configured to supply plural first heat dissipation materials. The at least one second feeding module is detachably disposed in the first concave or the second concave, and configured to supply plural second heat dissipation materials. The at least one first feeding module is different from the at least one second feeding module, and a size of the first heat dissipation materials is different from a size of the second heat dissipation materials. The first deployment module is disposed on the platform movably along an X axis, a Y axis, and a Z axis. The first deployment module is configured to suck the first heat dissipation materials or the second heat dissipation materials from the first feeding region, and deliver and attach the first heat dissipation materials or the second heat dissipation materials. The second deployment module is disposed on the platform movably along the X axis, the Y axis, and the Z axis. The second deployment module is configured to suck the first heat dissipation materials or the second heat dissipation materials from the second feeding region, and deliver and attach the first heat dissipation materials or the second heat dissipation materials.

According to an example of the present disclosure, the first feeding module is a tray feeding module, and the second feeding module is a feeder feeding module.

According to an example of the present disclosure, the tray feeding module includes a tray and two holders. The tray is configured to carry the first heat dissipation materials. The two holders are respectively disposed at two opposite sides of the first concave or two opposite sides of the second concave to carry and hold the tray. The feeder feeding module includes a switching module, at least one feeder, and at least one tape-on-reel. The switching module is disposed in the first concave or the second concave. The feeder is disposed on the switching module. The tape-on-reel is disposed on the feeder.

According to an example of the present disclosure, a number of each of the at least one feeder and the at least one tape-on-reel is two, and the feeders carry the tape-on-reels respectively and correspondingly.

According to an example of the present disclosure, a first one of the tape-on-reels is configured to carry the second heat dissipation materials. A second one of the tape-on-reels is configured to carry plural third heat dissipation materials, and a size of the third heat dissipation materials is different from the size of the second heat dissipation materials.

According to an example of the present disclosure, the platform further includes a first working region and a second working region. The heat dissipation material attaching apparatus further includes a delivery device extendedly disposed in the first working region and the second working region, and the delivery device is configured to deliver plural substrates along a direction. The first deployment module is configured to attach the first heat dissipation materials or the second heat dissipation materials on the substrates in the first working region, and the second deployment module is configured to attach the first heat dissipation materials or the second heat dissipation materials on the substrates in the second working region.

According to the objective of the present disclosure, a heat dissipation material attaching apparatus is further provided, which includes a platform, at least one first feeding module, at least one second feeding module, a first deployment module, and a second deployment module. The platform includes a first feeding region and a second feeding region. The first feeding region and the second feeding region respectively have a first concave and a second concave recessed into the platform. The first feeding module is detachably disposed in the first concave or the second concave and configured to supply plural first heat dissipation materials. The second feeding module is detachably disposed in the first concave or the second concave and configured to supply plural second heat dissipation materials. The first feeding module is the same as or different from the second feeding module, and a size of the first heat dissipation materials is correspondingly the same as or different from a size of the second heat dissipation materials. The first deployment module is disposed on the platform movably long an X axis, a Y axis, and a Z axis. The first deployment module is configured to suck the first heat dissipation materials or the second heat dissipation materials from the first feeding region, and deliver and attach the first heat dissipation materials or the second heat dissipation materials. The second deployment module is disposed on the platform movably along the X axis, the Y axis, and the Z axis. The second deployment module is configured to suck the first heat dissipation materials or the second heat dissipation materials from the second feeding region, and deliver and attach the first heat dissipation materials or the second heat dissipation materials.

According to an example of the present disclosure, the first feeding module is a tray feeding module, and the second feeding module is feeder feeding module.

According to an example of the present disclosure, the tray feeding module includes a tray and two holders. The tray is configured to carry the first heat dissipation materials. The two holders are respectively disposed at two opposite sides of the first concave or two opposite sides of the second concave to carry and hold the tray. The feeder feeding module includes a switching module, at least one feeder, and at least one tape-on-reel. The switching module is disposed in the first concave or the second concave. The feeder is disposed on the switching module. The tape-on-reel is disposed on the feeder.

According to the objective of the present disclosure, a heat dissipation material feeding method is provided. In the method, a first feeding module and a second feeding module are disposed in a first feeding region and a second feeding region of a platform of a heat dissipation material attaching apparatus respectively, in which the first feeding module and the second feeding module are different from each other. Then, a feeding operation is performed to simultaneously use the first feeding module and the second feeding module to respectively supply plural first heat dissipation materials to a first deployment module of the heat dissipation material attaching apparatus and plural second heat dissipation materials to a second deployment module of the heat dissipation material attaching apparatus, in which a size of the first heat dissipation materials is different from a size of the second heat dissipation materials.

According to an example of the present disclosure, the first feeding module is a tray feeding module, and the second feeding module is a feeder feeding module.

According to an example of the present disclosure, the feeder feeding module includes a switching module, two feeders, and two tape-on-reels. The switching module is disposed in the platform. The two feeders are separately disposed on the switching module. The two tape-on-reels are respectively disposed on the feeders. A first one of the tape-on-reels carries the second heat dissipation materials, and a second one of the tape-on-reels carries plural third heat dissipation materials. A size of the third heat dissipation materials is different from the size of the first heat dissipation materials and the size of the second heat dissipation materials. Performing the feeding operation of the heat dissipation material feeding method further includes using the second feeding module to supply the third heat dissipation materials simultaneously.

According to the objective of the present disclosure, a heat dissipation material attaching method is provided. In the method, a feeding operation is performed on a platform of a heat dissipation material attaching apparatus to simultaneously use a first feeding module to supply plural first heat dissipation materials and a second feeding module to supply plural second heat dissipation materials. A size of the first heat dissipation materials is different from a size of the second heat dissipation materials, and the platform includes a first working region and a second working region. Then, a taking operation is performed to use a first deployment module and a second deployment module of the heat dissipation material attaching apparatus to suck the first heat dissipation materials from the first feeding module and the second heat dissipation materials from the second feeding module respectively. An attaching operation is then performed to use the first deployment module and the second deployment module to attach the first heat dissipation materials in the first working region and the second heat dissipation materials in the second working region respectively.

According to an example of the present disclosure, the attaching operation further includes using a delivery device of the heat dissipation material attaching apparatus to deliver plural substrates to the first working region, using the first deployment module to attach the first heat dissipation materials to the substrates respectively, using the delivery device to deliver the substrates from the first working region to the second working region, and using the second deployment module to attach the second heat dissipation materials to the substrates respectively.

According to an example of the present disclosure, the attaching operation further includes using a delivery device of the heat dissipation material apparatus to deliver plural first substrates and plural second substrates to the first working region and the second working region respectively, and using the first deployment module and the second deployment module simultaneously to attach the first heat dissipation materials to the first substrates and the second heat dissipation materials to the second substrates respectively.

According to an example of the present disclosure, the first feeding module is a tray feeding module, and the second feeding module is a feeder feeding module. The feeder feeding module includes two feeders, and two tape-on-reels respectively disposed on the feeders. A first one of the tape-on-reels carries the second heat dissipation materials, a second one of the tape-on-reels carries plural third heat dissipation materials. A size of the third heat dissipation materials is different from the size of the first heat dissipation materials and the size of the second heat dissipation materials. Performing the attaching operation further includes using a first placement head and a second placement head of the second deployment module to respectively suck the second heat dissipation materials and the third heat dissipation materials, and using the first placement head and the second placement head to attach the second heat dissipation materials and the third heat dissipation materials to the substrates on the second working region.

### BRIEF DESCRIPTION OF THE DRAWINGS

Aspects of the present disclosure are best understood from the following detailed description in conjunction with the accompanying figures. It is noted that in accordance with the standard practice in the industry, various features are not drawn to scale. In fact, dimensions of the various features can be arbitrarily increased or reduced for clarity of discussion.

FIG. 1 is a schematic top view of a configuration of a heat dissipation material attaching apparatus according to a first embodiment of the present disclosure.

FIG. 2 is a schematic three-dimensional diagram of a heat dissipation material attaching apparatus according to the first embodiment of the present disclosure.

FIG. 3 is a schematic top view of a configuration of a heat dissipation material attaching apparatus according to a second embodiment of the present disclosure.

FIG. 4 is a schematic top view of a configuration of a heat dissipation material attaching apparatus according to a third embodiment of the present disclosure.

FIG. 5 is a flowchart of a heat dissipation material feeding method according to an embodiment of the present disclosure.

FIG. 6 is a flowchart of a heat dissipation material attaching method according to an embodiment of the present disclosure.

### DETAILED DESCRIPTION

The embodiments of the present disclosure are discussed in detail below. However, it will be appreciated that the embodiments provide many applicable concepts that can be implemented in various specific contents. The embodiments discussed and disclosed are for illustrative purposes only and are not intended to limit the scope of the present disclosure. All of the embodiments of the present disclosure disclose various different features, and these features may be implemented separately or in combination as desired.

In addition, the terms "first", "second", and the like, as used herein, are not intended to mean a sequence or order, and are merely used to distinguish elements or operations described in the same technical terms.

The spatial relationship between two elements described in the present disclosure applies not only to the orientation depicted in the drawings, but also to the orientations not represented by the drawings, such as the orientation of the inversion. Moreover, the terms "connected", "electrically connected", or the like between two components referred to in the present disclosure are not limited to the direct connection or electrical connection of the two components, and may also include indirect connection or electrical connection as required.

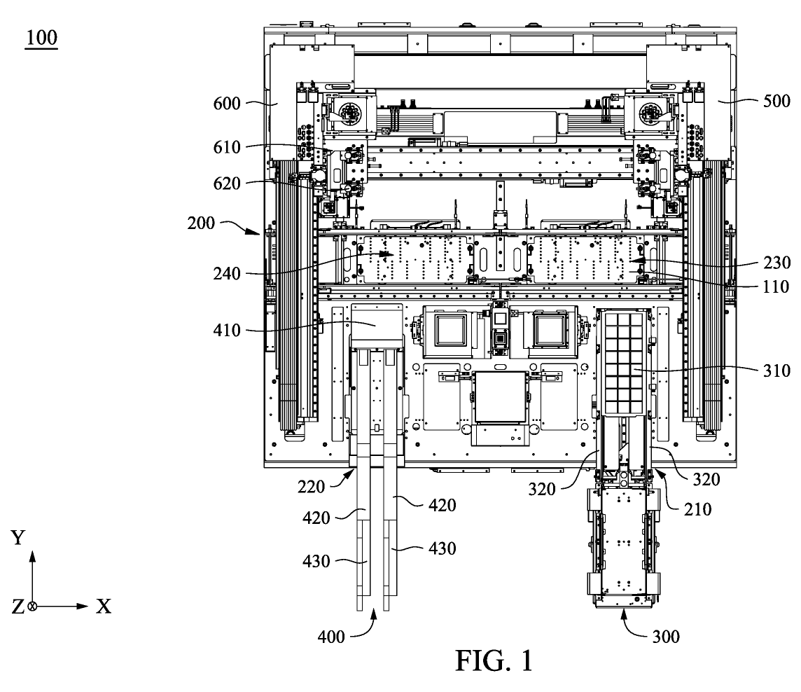

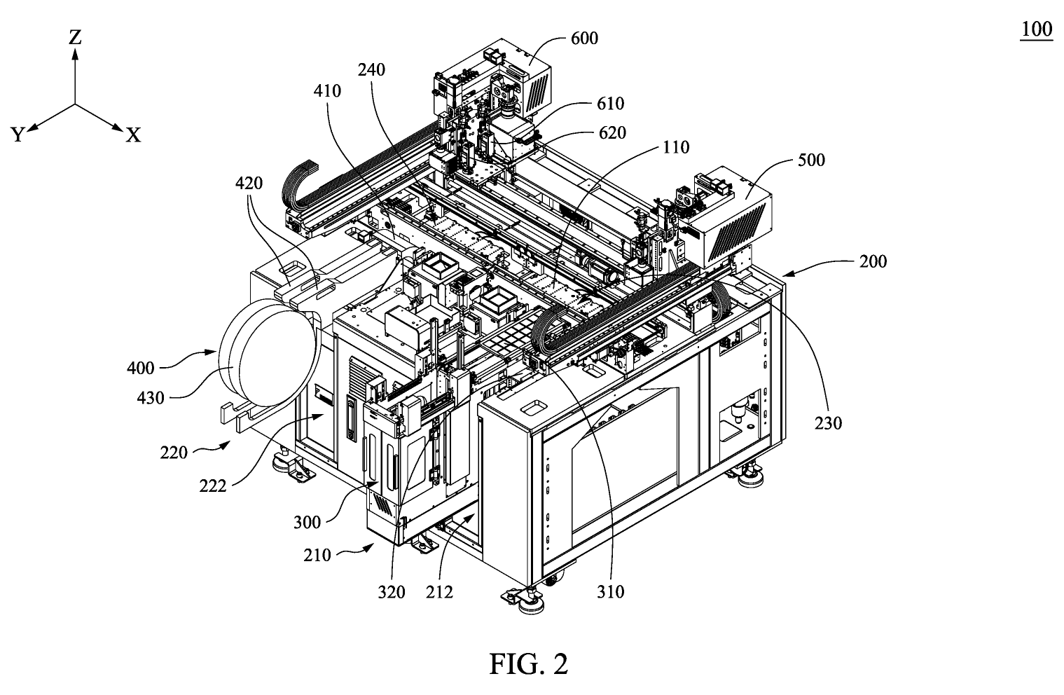

Referring to FIG. 1 and FIG. 2, FIG. 1 and FIG. 2 respectively illustrate a schematic top view of a configuration and a schematic three-dimensional diagram of a heat dissipation material attaching apparatus 100 according to a first embodiment of the present disclosure. The heat dissipation material attaching apparatus 100 may mainly include a platform 200, at least one first feeding module 300, at least one second feeding module 400, a first deployment module 500, and a second deployment module 600.

The platform 200 may be a box structure, and may be used to carry the at least one first feeding module 300, the at least one second feeding module 400, the first deployment module 500, and the second deployment module 600. The platform 200 includes a first feeding region 210 and a second feeding region 220. The first feeding region 210 and the second feeding region 220 are separated from each other, and may be disposed, for example, in parallel on one side of the platform 200. As shown in FIG. 2, the first feeding region 210 and the second feeding region 220 have a first concave 212 and a second concave 222 respectively. The first concave 212 and the second concave 222 are both recessed into the platform 200, and respectively have recessed spaces for accommodating the first feeding module 300 or the second feeding module 400. That is, the first concave 212 may accommodate the first feeding module 300 or the second feeding module 400, and the second concave 222 may accommodate the first feeding module 300 or the second feeding module 400.

In some examples, the platform 200 further includes a first working region 230 and a second working region 240. For example, the first working region 230 and the second working region 240 may be in a strip shape. The first working region 230 and the second working region 240 may be adjacent to each other. In some examples, the first working region 230 and the second working region 240 are adjacent to a center of the platform 200, parallel to a direction X across the platform 200, and perpendicular to the first feeding region 210 and the second feeding region 220. The first working region 230 and the second working region 240 may be disposed on the platform 200 in different orientations, and the present disclosure is not limited thereto.

The first feeding module 300 is detachably disposed in the first concave 212 or the second concave 222 to supply first heat dissipation materials. In the present embodiment, the first feeding module 300 is a tray feeding module and includes a tray 310 and two holders 320. The tray 310 may have a grid structure arranged in an array and carry plural first heat dissipation materials. The two holders 320 are in a strip shape. In the example shown in FIG. 2, the first feeding module 300 is disposed in the first concave 212, and the two holders 320 are respectively and parallelly disposed at two opposite sides of the first concave 212 to carry and hold the tray 310. Specifically, the tray 310 is disposed and fixed on the two holders 320. The first feeding module 300 is fixed in the first concave 212 by the two holders 320.

The second feeding module 400 is detachably disposed in the first concave 212 or the second concave 222 to supply second heat dissipation materials. In the present embodiment, the second feeding module 400 is disposed in the second concave 222. The second feeding module 400 and the first feeding module 300 are different feeding module, and a size of the second heat dissipation materials is different from a size of the first heat dissipation materials. The size of the first heat dissipation materials may be greater than, equal to, or smaller than the size of the second heat dissipation materials. In some examples, the second feeding module 400 is a feeder feeding module, and includes a switching module 410, at least one feeder 420, and at least one tape-on-reel 430. In the example shown in FIG. 2, the switching module 410 is disposed in the second concave 222. The feeder 420 is disposed on the switching module 410. The tape-on-reel 430 is disposed on the feeder 420 and a number of the tape-on-reel 430 is corresponding to a number of the feeder 420.

Typically, compared with the feeder feeding module, the tray feeding module may carry heat dissipation materials of a greater size. Therefore, in the example that the first feeding module 300 is the tray feeding module and the second feeding module 400 is the feeder feeding module, the size of the first heat dissipation materials is usually greater than the size of the second heat dissipation materials.

In some examples, the number of the feeder 420 and the number of the tape-on-reel 430 are both two. The feeders 420 carry the tape-on-reels 430 correspondingly and respectively. In such an example, one of the tape-on-reels 430 carries the second heat dissipation materials and the other one of the tape-on-reels 430 may carry third heat dissipation materials. A size of the third heat dissipation materials is different from the size of the size of the second heat dissipation materials. However, the two tape-on-reels 430 may carry the same heat dissipation materials.

In some examples, the heat dissipation material attaching apparatus 100 further includes a delivery device 110. The delivery device 110 is disposed extendedly in the first working region 230 and the second working region 240, and may deliver plural substrates in a direction along the first working region 230 and the second working region 240. In the example that the first working region 230 and the second working region 240 are parallel to the direction X, the delivery device 110 delivers the substrates parallel to the direction X, for example, from left to right along the direction X, but it is not limited thereto.

The first deployment module 500 may be disposed on the platform movably along the direction X, a direction Y, and a direction Z, in which the direction X, the direction Y, and the direction Z are perpendicular to each other. The first deployment module 500 may suck the first heat dissipation materials or the second heat dissipation materials from the first feeding region 210, and deliver and attach the first heat dissipation materials or the second heat dissipation materials. Specifically, the first deployment module 500 may first move to the first feeding region 210 along the direction X and the direction Y, and then move along the direction Z to suck the first heat dissipation materials supplied by the first feeding region 210. Subsequently, the first deployment module 500 may move along the direction X and the direction Y to deliver the first heat dissipation materials from the first feeding region 210 to the first working region 230, and then attach the first heat dissipation materials on the substrates delivered by the delivery device 110 in the first working region 230.

The second deployment module 600 may be disposed on the platform movably along the direction X, the direction Y, and the direction Z similarly. The second deployment module 600 and the first deployment module 500 are separated, and are disposed on the platform 200 symmetrically. The second deployment module 600 may suck the first heat dissipation materials or the second heat dissipation materials from the second feeding region 220, and deliver and attach the first heat dissipation materials or the second heat dissipation materials. The second deployment module 600 may first move along the direction X and the direction Y to the second feeding region 220, and then move along the direction Z to suck the second heat dissipation materials supplied by the second feeding region 220 to deliver the second heat dissipation materials to the second working region 240. Subsequently, the second deployment module 600 attaches the second heat dissipation materials on the substrates delivered by the delivery device 110 in the second working region 240.

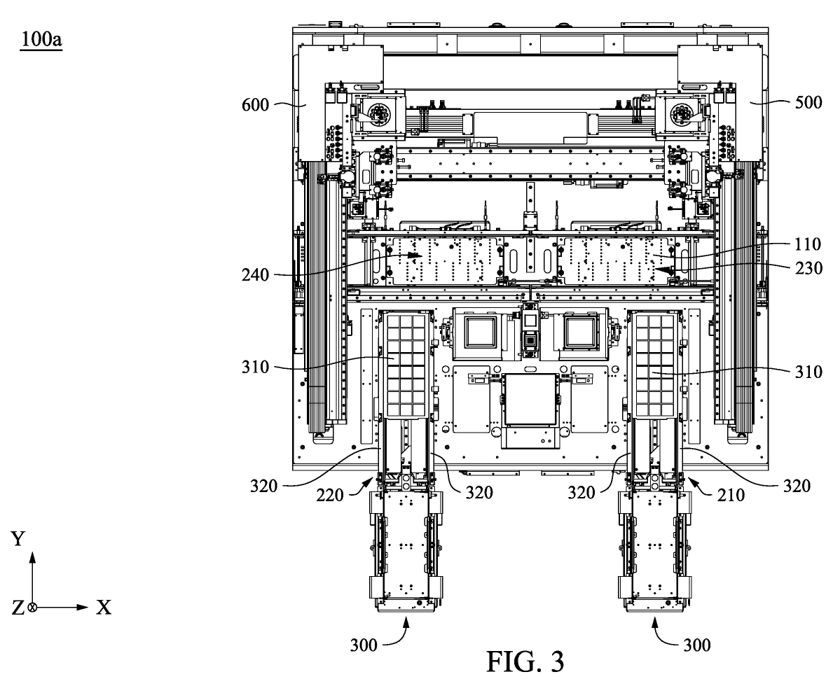

Referring to FIG. 3, FIG. 3 is a schematic top view of a configuration of a heat dissipation material attaching apparatus 100a according to a second embodiment of the present disclosure. The structure of the heat dissipation material attaching apparatus 100a and the heat dissipation material attaching apparatus 100 are substantially the same, and a difference between the heat dissipation material attaching apparatus 100a and 100 is that the heat dissipation material attaching apparatus 100a includes two first feeding modules 300. The two first feeding modules 300 are respectively disposed in the first concave 212 and the second concave 222. At this time, heat dissipation materials disposed in the first feeding region 210 and the second feeding region 220 are first heat dissipation materials.

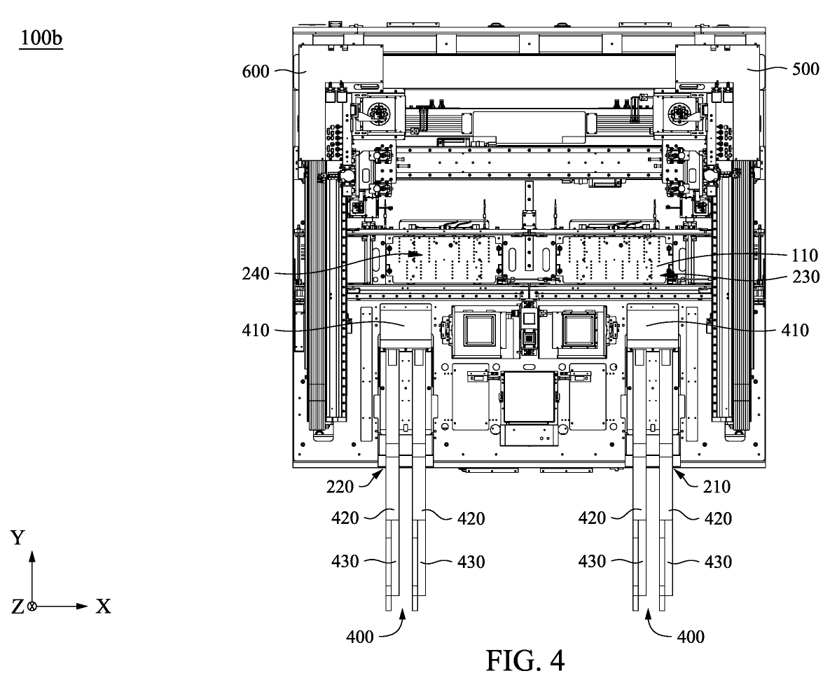

Referring to FIG. 4, FIG. 4 is a schematic top view of a configuration of a heat dissipation material attaching apparatus 100b according to a third embodiment of the present disclosure. The structure of the heat dissipation material attaching apparatus 100b is substantially the same as the structure of the heat dissipation material attaching apparatus 100, and a difference between the heat dissipation material attaching apparatus 100b and 100 is that the heat dissipation material attaching apparatus 100b includes two second feeding modules 400. The two second feeding modules 400 are respectively disposed in the first concave 212 and the second concave 222. In some examples, heat dissipation materials supplied by the first feeding region 210 and the second feeding region 220 are second heat dissipation materials. In other examples, the second feeding modules 400 may carry heat dissipation materials of various different sizes, such that the first feeding region 210 and the second feeding region 220 may supply the heat dissipation materials of the different sizes.

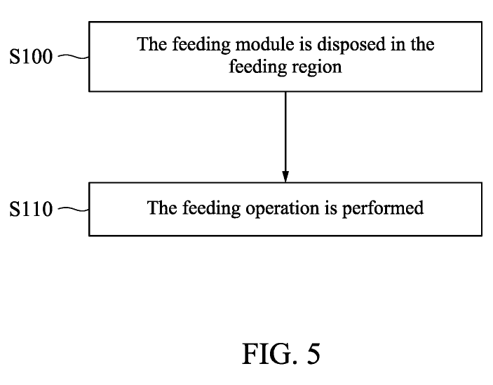

Referring to FIG. 5, FIG. 5 is a flowchart of a heat dissipation material feeding method according to an embodiment of the present disclosure. When the heat dissipation material feeding method is performed, a step S100 may be first performed to dispose the feeding modules in the feeding regions. In the example shown in FIG. 2, the first feeding module 300 and the second feeding module 400 are respectively disposed in the first concave 212 of the first feeding region 210 and the second concave 222 of the second feeding region 220 in the platform 200 of the heat dissipation material attaching apparatus 100. In other examples, the first feeding module 300 and the second feeding module 400 are interchanged and are respectively disposed in the second concave 222 and the first concave 212.

In the example shown in FIG. 3, in the step S100 respectively disposes, the two first feeding modules 300 are respectively disposed in the first concave 212 of the first feeding region 210 and the second concave 222 of the second feeding region 220. In the example shown in FIG. 4, in the step S100, the two second feeding module 400 are disposed in the first concave 212 of the first feeding region 210 and the second concave 222 of the second feeding region 220.

After the feeding modules are disposed in the feeding regions, a step S110 may be performed to use the feeding modules to perform a feeding operation. In the example shown in FIG. 1, in the step S110, the first feeding module 300 and the second feeding module 400 are simultaneously used to respectively supply the first heat dissipation materials to the first deployment module 500 of the heat dissipation material attaching apparatus 100 and the second heat dissipation materials to the second deployment module 600. Specifically, the first deployment module 500 and the second deployment module 600 respectively move to tops of the first feeding module 300 and the second feeding module 400 along the direction X and the direction Y, and then move along the direction Z to respectively suck the first heat dissipation materials and the second heat dissipation materials.

In the example that the second feeding module 400 includes two feeders 420 and two tape-on-reels 430, when one of the tape-on-reels 430 carries the second heat dissipation materials and the other one of the tape-on-reels 430 carries the third heat dissipation materials, performing the feeding operation further includes using the second feeding module 400 to simultaneously supply the second heat dissipation materials and the third heat dissipation materials.

In the example shown in FIG. 3, the step S110 is performed to use two first feeding modules 300 to supply the first heat dissipation materials to the first deployment module 500 and the second deployment module 600 of the heat dissipation material attaching apparatus 100a respectively. Specifically, the first deployment module 500 and the second deployment module 600 respectively move to the tops of the first feeding region 210 and the second feeding region 220, and move along the direction Z to suck the first heat dissipation materials supplied by the first feeding modules 300 in the first feeding region 210 and the second feeding region 220 respectively.

In the example shown in FIG. 4, the step S110 is performed to use two second feeding modules 400 to perform the feeding operation. The first deployment module 500 and the second deployment module 600 respectively move to the tops of the first feeding region 210 and the second feeding region 220 along the direction X and the direction Y, and then move along the direction Z to respectively suck the second heat dissipation materials supplied by the second feeding modules 400 in the first feeding region 210 and the second feeding region 220. In addition, in some examples, the second feeding modules 400 may carry heat dissipation materials of different sizes, such as the second heat dissipation materials and the third heat dissipation materials. Therefore, in such examples, the second feeding modules 400 can supply the second heat dissipation materials and the third heat dissipation materials simultaneously.

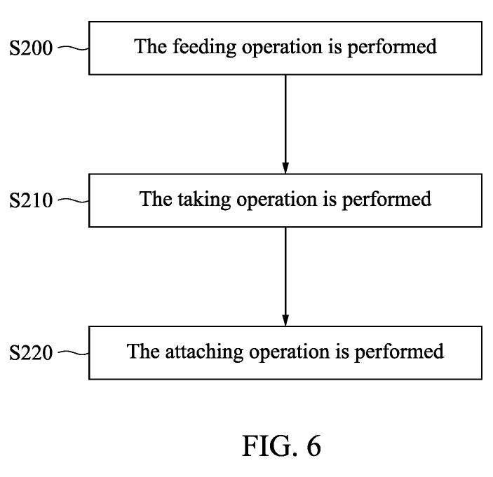

Referring to FIG. 1 and FIG. 6, in which FIG. 6 is a flowchart of a heat dissipation material attaching method according to an embodiment of the present disclosure. When the heat dissipation material attaching method is performed, a step S200 may be first performed to simultaneously use the first feeding module 300 and the second feeding module 400 to perform a feeding operation on the platform 200 of the heat dissipation material attaching apparatus 100 and supply the first heat dissipation materials and the second heat dissipation materials of different sizes respectively.

After the feeding operation is completed, a step S210 may be performed to use the first deployment module 500 and the second deployment module 600 to perform a taking operation. Specifically, in the example shown in FIG. 1, the first deployment module 500 and the second deployment module 600 are moved along the direction X and the direction Y to the tops of the first feeding module 300 and the second feeding module 400 respectively, and then the first deployment module 500 and the second deployment module 600 are moved along the direction Z to respectively suck the first heat dissipation materials from the first feeding module 300 and the second heat dissipation materials from the second feeding module 400.

After the taking operation is completed, a step S220 may be performed to use the first deployment module 500 and the second deployment module 600 to perform an attaching operation on the platform 200 of the heat dissipation material attaching apparatus 100. In some examples, in the performing of the attaching operation, the delivery device 110 is first used to deliver plural substrates to the first working region 230. The first deployment module 500 is then moved from the first feeding module 300 to the first working region 230, and the first deployment module 500 is used to attach the first heat dissipation materials on the substrates respectively. Then, the delivery device 110 is used again to deliver the substrates from the first working region 230 to the second working region 240. Subsequently, the second deployment module 600 is moved from the second feeding module 400 to the second working region 240, and the second deployment module 600 is used to respectively attach the second heat dissipation materials on the substrates that have been attached with the first heat dissipation materials.

In some examples, when the attaching operation is performed, plural first substrates and plural second substrates to be attached with the heat dissipation materials are already disposed in the first working region 230 and the second working region 240 respectively. In other examples, when the attaching operation is performed, the delivery device 110 is used to deliver the first substrates and the second substrates to the first working region 230 and the second working region 240 respectively. When the attaching operation is performed, the first deployment module 500 moves from the first feeding module 300 to the first working region 230, and attaches the sucked first heat dissipation materials on the first substrates in the first working region 230. The second deployment module 600 moves from the second feeding module 400 to the second working region 240, and attaches the sucked second heat dissipation materials on the second substrates in the second working region 240.

It should be noted that, when the attaching operation of the present disclosure is performed, the operations that the first deployment module 500 attaches the first heat dissipation materials on the first substrates and the second deployment module 600 attaches the second heat dissipation materials on the second substrates may be performed simultaneously or alternately in time. In other words, the heat dissipation material attaching operation in the first working region 230 and the heat dissipation material attaching operation in the second working region 240 may be performed simultaneously, or may be performed alternately in time based on actual requirements, for example, the operations must be completed sequentially according to mechanical or spatial requirements. However, the present disclosure is not limited thereto.

In the example that the second feeding module 400 supplies the second heat dissipation materials and the third heat dissipation materials simultaneously, the second deployment module 600 may include a first deployment head 610 and a second deployment head 620. The first deployment head 610 and the second deployment head 620 of the second deployment module 600 suck the second heat dissipation materials and the third heat dissipation materials respectively and correspondingly. In the example, the first deployment head 610 and the second deployment head 620 move from the second feeding region 220 to the second working region 240, and attach the sucked second heat dissipation materials and the sucked third heat dissipation materials on the second substrates in the second working region 240 respectively.

It can be seen from the aforementioned embodiments that the heat dissipation material attaching apparatus of the present disclosure can provide continuous operations of feeding and attaching heat dissipation materials of different sizes according to the needs of the heat dissipation materials of the different sizes. In the heat dissipation material attaching operation, if there is a need to attach heat dissipation materials of different sizes, the continuous operations of feeding and attaching can be directly performed in the heat dissipation material attaching apparatus of the present disclosure. Therefore, it is unnecessary to additionally set up another attaching apparatus, and wait for the attaching operation of the heat dissipation materials of the first size being completed before the attaching operation of the next heat dissipation materials of the other size is performed. Accordingly, the operation process can be simplified, and the waiting time of the operation can be saved.

Another advantage of the present disclosure is that the heat dissipation material attaching apparatus of the present disclosure can achieve the continuous operations of feeding and attaching the heat dissipation materials of the different sizes. Therefore, compared with the conventional apparatuses, a number of the required apparatuses and the space required for the apparatuses can be decreased.

Although the present disclosure has been disclosed above with embodiments, it is not intended to limit the present disclosure. Any person having ordinary skill in the art can make various changes and modifications without departing from the spirit and scope of the present disclosure. Therefore, the protection scope of the present disclosure should be defined by the scope of the appended claims.

What is claimed is:

1. A heat dissipation material attaching apparatus, comprising:
a platform comprising a first feeding region and a second feeding region, wherein the first feeding region and the second feeding region respectively have a first concave and a second concave recessed into the platform;
at least one first feeding module detachably disposed in the first concave or the second concave, and configured to supply a plurality of first heat dissipation materials;
at least one second feeding module detachably disposed in the first concave or the second concave, and configured to supply a plurality of second heat dissipation materials, wherein the at least one first feeding module is different from the at least one second feeding module, and a size of the first heat dissipation materials is different from a size of the second heat dissipation materials;
a first deployment module disposed on the platform movably along an X axis, a Y axis, and a Z axis, wherein the first deployment module is configured to suck the first heat dissipation materials or the second heat dissipation materials from the first feeding region, and deliver and attach the first heat dissipation materials or the second heat dissipation materials; and
a second deployment module disposed on the platform movably along the X axis, the Y axis, and the Z axis, wherein the second deployment module is configured to suck the first heat dissipation materials or the second heat dissipation materials from the second feeding region, and deliver, and attach the first heat dissipation materials or the second heat dissipation materials.

2. The heat dissipation material attaching apparatus of claim 1, wherein each of the at least one first feeding module is a tray feeding module, and each of the at least one second feeding module is a feeder feeding module.

3. The heat dissipation material attaching apparatus of claim 2, wherein:
the tray feeding module comprises:
a tray configured to carry the first heat dissipation materials; and
two holders respectively disposed at two opposite sides of the first concave or two opposite sides of the second concave to carry and hold the tray; and
the feeder feeding module comprises:
a switching module disposed in the first concave or the second concave;
at least one feeder disposed on the switching module; and
at least one tape-on-reel disposed on the at least one feeder.

4. The heat dissipation material attaching apparatus of claim 3, wherein a number of each of the at least one feeder and the at least one tape-on-reel is two, the feeders carry the tape-on-reels respectively and correspondingly.

5. The heat dissipation material attaching apparatus of claim 4, wherein a first one of the tape-on-reels is configured to carry the second heat dissipation materials, a second one of the tape-on-reels is configured to carry a plurality of third heat dissipation materials, a size of the third heat dissipation materials is different from the size of the second heat dissipation materials.

6. The heat dissipation material attaching apparatus of claim 1, wherein:
the platform further comprises a first working region and a second working region;
the heat dissipation material attaching apparatus further comprises a delivery device extendedly disposed in the first working region and the second working region, and the delivery device is configured to deliver a plurality of substrates along a direction; and
the first deployment module is configured to attach the first heat dissipation materials or the second heat dissipation materials on the substrates in the first working region, and the second deployment module is configured to attach the first heat dissipation materials or second heat dissipation materials on the substrates in the second working region.

7. A heat dissipation material attaching apparatus, comprising:
a platform comprising a first feeding region and a second feeding region, wherein the first feeding region and the second feeding region respectively have a first concave and a second concave recessed into the platform;
at least one first feeding module detachably disposed in the first concave or the second concave and configured to supply a plurality of first heat dissipation materials;
at least one second feeding module detachably disposed in the first concave or the second concave and configured to supply a plurality of second heat dissipation materials, wherein the at least one first feeding module is the same as or different from the at least one second feeding module, and a size of the first heat dissipation materials is correspondingly the same as or different from a size of the second heat dissipation materials;
a first deployment module disposed on the platform movably long an X axis, a Y axis, and a Z axis, wherein the first deployment module is configured to suck the first heat dissipation materials or the second heat dissipation materials from the first feeding region, and deliver, and attach the first heat dissipation materials or the second heat dissipation materials; and
a second deployment module disposed on the platform movably along the X axis, the Y axis, and the Z axis, wherein the second deployment module is configured to suck the first heat dissipation materials or the second heat dissipation materials from the second feeding region, and deliver and attach the first heat dissipation materials or the second heat dissipation materials.

8. The heat dissipation material attaching apparatus of claim 7, wherein each of the at least one first feeding module is a tray feeding module, and each of the at least one second feeding module is feeder feeding module.

9. The heat dissipation material attaching apparatus of claim 8, wherein:
the tray feeding module comprises:
a tray configured to carry the first heat dissipation materials; and
two holders respectively disposed at two opposite sides of the first concave or two opposite sides of the second concave to carry and hold the tray; and
the feeder feeding module comprises:
a switching module disposed in the first concave or the second concave;
at least one feeder disposed on the switching module; and
at least one tape-on-reel disposed on the at least one feeder.

10. A heat dissipation material feeding method, comprising:
disposing a first feeding module and a second feeding module in a first feeding region and a second feeding region of a platform of a heat dissipation material attaching apparatus respectively, wherein the first feeding module and the second feeding module are different from each other; and
performing a feeding operation to simultaneously use the first feeding module and the second feeding module to respectively supply a plurality of first heat dissipation materials to a first deployment module of the heat dissipation material attaching apparatus and a plurality of second heat dissipation materials to a second deployment module of the heat dissipation material attaching apparatus, wherein a size of the first heat dissipation materials is different from a size of the second heat dissipation materials.

11. The heat dissipation material feeding method of claim 10, wherein the first feeding module is a tray feeding module, and the second feeding module is a feeder feeding module.

12. The heat dissipation material feeding method of claim 11, wherein the feeder feeding module comprises:
a switching module disposed in the platform;
two feeders separately disposed on the switching module; and
two tape-on-reels respectively disposed on the feeders, wherein a first one of the tape-on-reels carries the second heat dissipation materials, a second one of the tape-on-reels carries a plurality of third heat dissipation materials, a size of the third heat dissipation materials is different from the size of the first heat dissipation materials and the size of the second heat dissipation materials,
wherein performing the feeding operation further comprises using the second feeding module to supply the third heat dissipation materials simultaneously.

13. A heat dissipation material attaching method, comprising:
performing a feeding operation on a platform of a heat dissipation material attaching apparatus to simultaneously use a first feeding module to supply a plurality of first heat dissipation materials and a second feeding module to supply a plurality of second heat dissipation materials, wherein a size of the first heat dissipation materials is different from a size of the second heat dissipation materials, and the platform comprises a first working region and a second working region;
performing a taking operation to use a first deployment module and a second deployment module of the heat dissipation material attaching apparatus to suck the first heat dissipation materials from the first feeding module and the second heat dissipation materials from the second feeding module respectively; and
performing an attaching operation to use the first deployment module and the second deployment module to attach the first heat dissipation materials in the first working region and the second heat dissipation materials in the second working region respectively.

14. The heat dissipation material attaching method of claim 13, wherein performing the attaching operation further comprises:
using a delivery device of the heat dissipation material attaching apparatus to deliver a plurality of substrates to the first working region;
using the first deployment module to attach the first heat dissipation materials to the substrates respectively;
using the delivery device to deliver the substrates from the first working region to the second working region; and
using the second deployment module to attach the second heat dissipation materials to the substrates respectively.

15. The heat dissipation material attaching method of claim 13, wherein performing the attaching operation comprises:
using a delivery device of the heat dissipation material attaching apparatus to deliver a plurality of first substrates and a plurality of second substrates to the first working region and the second working region respectively; and
using the first deployment module and the second deployment module simultaneously to attach the first heat dissipation materials to the first substrates and the second heat dissipation materials to the second substrates respectively.

16. The heat dissipation material attaching method of claim 13, wherein:
the first feeding module is a tray feeding module, and the second feeding module is a feeder feeding module;
the feeder feeding module comprises two feeders and two tape-on-reels respectively disposed on the feeders, a first one of the tape-on-reels carries the second heat dissipation materials, a second one of the tape-on-reels carries a plurality of third heat dissipation materials, a size of the third heat dissipation materials is different from the size of the first heat dissipation materials and the size of the second heat dissipation materials; and
performing the attaching operation further comprises using a first placement head and a second placement head of the second deployment module to respectively suck the second heat dissipation materials and the third heat dissipation materials, and using the first placement head and the second placement head to attach at least one of the second heat dissipation materials and at least one of the third heat dissipation materials to each of a plurality of substrates on the second working region.
